(19) United States
(12) Patent Application Publication
(10) Pub. No.: US 2003/0079335 A1
(43) Pub. Date: May 1, 2003

(54) Manufacturing method for legless electronics parts

(75) Inventor: Yao-Tsung Chi, Pa Te City (TW)

Correspondence Address: DOUGHERTY & TROXELL, Suite 1404, 5205 Leesburg Pike, Falls Church, VA, 22041, US

(73) Assignee: CHU JHI ELECTRONICS CO., LTD.

(21) Appl. No.: 09/983,828

(22) Filed: Oct. 26, 2001

(51) Int. Cl. H01C 17/00; H05K 3/02; G05F 1/00

(52) U.S. Cl. 29/610.1; 29/847; 29/593

(57) ABSTRACT

A manufacturing method for legless electronic parts used in a surface mounting type printing circuit board is disclosed. The legless electronic parts are made from leg type electronic elements. The method comprises the steps of: manufacturing a leg type electronic part and painting; cutting legs of a leg type parts to become legless electronic parts; pressing metal caps into two ends of the legless parts for replacing the legs; testing the resistance of a legless parts for determining the resistance, error and fault ratio; removing unqualified parts; and packing the tested parts.

### BACKGROUND OF THE INVENTION

(1) Field of the Invention

The present invention relates to a manufacturing method for legless electronic parts, and especially to electronic parts used in a surface mounting type printed circuit board; the conventional leg type electronic part is remanufactured as a legless electronic part.

(2) Description of the Prior Art

With the advance of the industrial technology, the conventional pin through hole printed circuit board has been replaced by surface mount type printed circuit board for matching the improvement of integrated circuit board and the requirement of compactness.

Current used surface mounting technological device is very expensive. Thereby, the electronic parts used in surface mounting technology can not be used in conventional electronic parts, such as resistors, inductors, capacitors, and diodes. The reason is that the conventional electronic parts have larger sizes and have legs which are suitable for pin through hole printed circuit board. Therefore, the surface mounting device is expensive.

Taiwan Patent No. 029170, “Transmission Device of a leg type resistor coating machine”, discloses a transmission device used force coating and machining leg type resistors, inductors, diodes, and other electronic parts. From above description, it is known, other than legs, the legless electronic parts are almost identical to the conventional electronic parts.

### SUMMARY OF THE INVENTION

Accordingly, the primary object of the present invention is to provide a manufacturing method for legless electronic parts which adapts the advantage of the conventional manufacturing way so that no further cost is necessary to be used in SMD coating machine. In the following, an embodiment of manufacturing electronic parts are used, wherein the flow diagram and schematic perspective view of legless resistors of the present invention are illustrated. The process comprises the following steps. Legs of a leg type resistor cut to become legless resistor. Two ends of the legless resistor are pressed with metal hats, respectively, for replacing the legs. Test the resistance of a legless resistor for assuring the resistance, error and fault ratio. Remove bad parts. Pack the tested parts.

The various objects and advantages of the present invention will be more readily understood from the following detailed description when read in conjunction with the appended drawing.

### BRIEF DESCRIPTION OF THE DRAWINGS

FIG. 1 is a schematic view of a semi-product of a conventional legless resistor.

FIG. 2 is a lateral schematic view showing that the conventional legless resistor is placed on a printed circuit board.

FIG. 3 is a flow diagram about the manufacturing process of the legless resistor of the present invention.

FIG. 4 is a schematic view of the manufacturing process of the legless resistor of the present invention.

FIG. 5 is a schematic perspective view showing that the legless resistor of the present invention is placed on a printed circuit board.

### DETAILED DESCRIPTION OF THE PREFERRED EMBODIMENTS

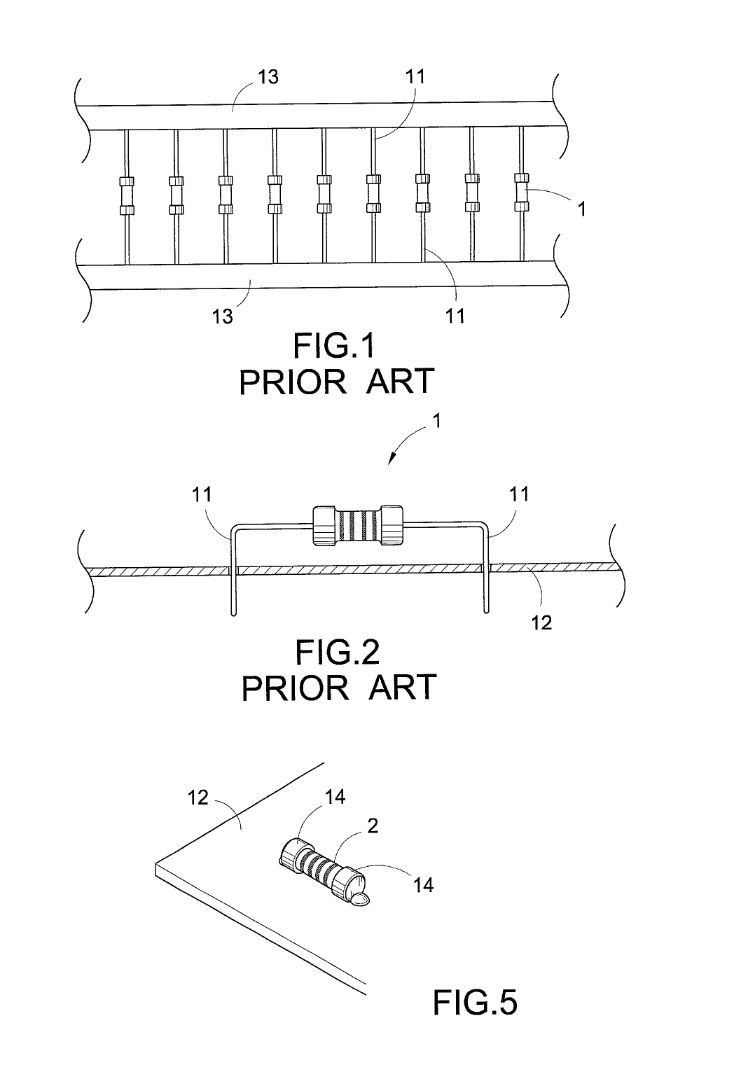

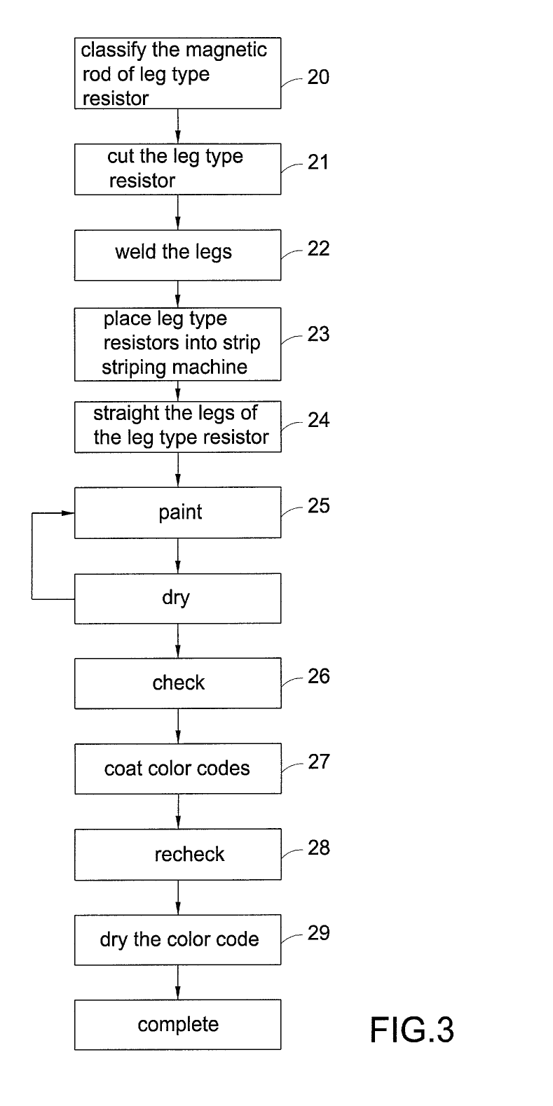

Referring to FIG. 1, the semi-product of a conventional leg type resistor is illustrated. In the present invention, the legless electronic elements are made by machines for manufacturing the conventional leg type resistors and by other extra steps. In the following, the manufacturing process for manufacturing the conventional leg type resistor 1 is used as an example. In general, the leg type resistor 1 has a specific impedance by forming slot on a resisting rod. Two ends of the resisting rod are welded with respective legs 11 for being inserted into the circuit board 12 (referring to FIG. 2). The distal end of each pin 11 of the leg type resistor 1 is connected to a connecting strip 13 which connects all legs of the leg type resistors 1. The process of manufacturing a leg type resistor 1 includes the following steps (referring to FIG. 3, the flow diagram of the conventional leg type resistor is illustrated):

Step 20: Classify the magnetic rod of leg type resistor based on the ranges of resistances.

Step 21: Cut the leg type resistor 1 for forming resistors with specific resistance.

Step 22: Weld the legs 11 to the two ends of the resistors, and thus complete the semi-products of the leg type resistors.

Step 23: Place leg type resistors into strip striping machine for striping the connecting strip 13 on the legs 11.

Step 24: Straight the legs 11 of the leg type resistor 1, wherein generally, the leg type resistors are bent, therefore, it must be straightened.

Step 25: Paint and dry the magnetic rods, repeat the processes 4 to 5 times.

Step 26: Check the resistance of the leg type resistor, if the error over a standard value, remove the resistance.

Step 27: Coat color codes to correct leg type resistors 1, thereby, users may know the resistances by the color codes.

Step 28: Recheck the resistance of the resistor 1 whether it is matched to an error and a color code.

Step 29: Dry the color code to complete the product of the leg type resistor.

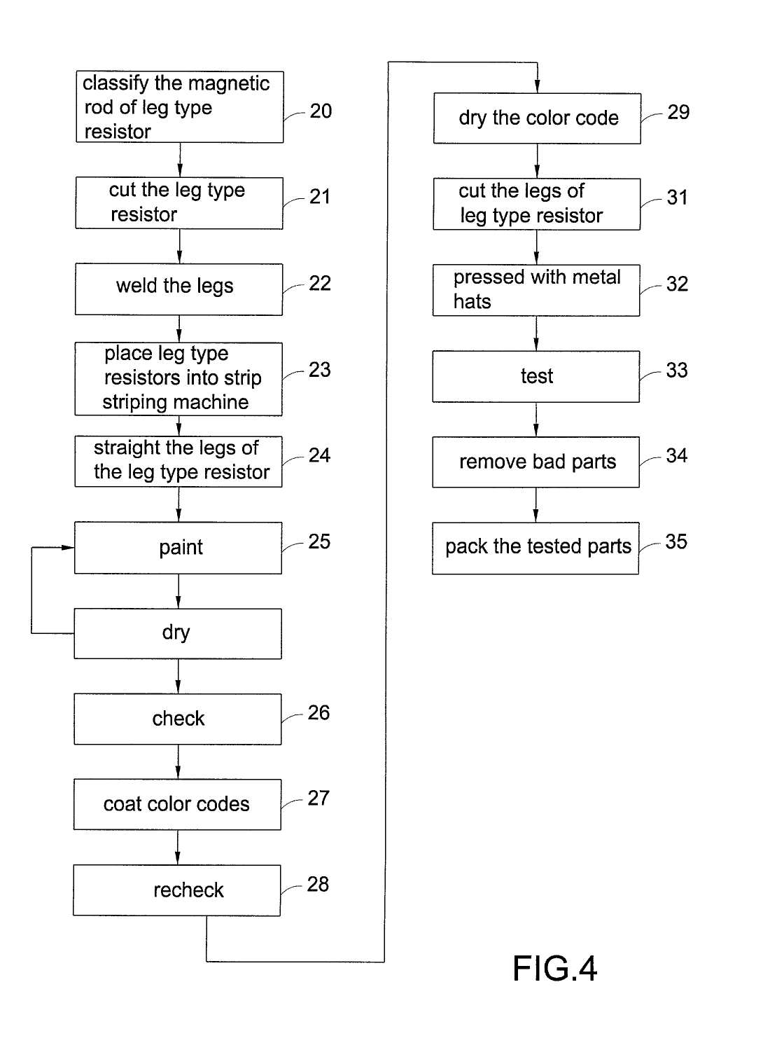

Above is the manufacturing process of leg type resistors 1. The conventional leg type resistor 1 has the advantages of lower cost, for example, the coating cost is farther lower than SMD elements. Therefore, the present invention adapts the advantage of the conventional manufacturing way so that no further cost is necessary to be used in SMD coating machine. In the following, an embodiment of manufacturing electronic parts are used, as shown in FIGS. 4 and 5, wherein the flow diagram and schematic perspective view of legless resistors of the present invention are illustrated. The process comprises the following steps:

Step 31: Cut the legs of a leg type resistor 1 become legless resistor 2.

Step 32: Two ends of the legless resistors 2 are pressed with metal hats 14, respectively, for replacing the legs 11.

Step 33: Test the resistance of a legless resistor 2 for assuring the resistance, error and fault ratio.

Step 34: Remove bad parts.

Step 35: Pack the tested parts.

By above steps, the conventional leg type resistor may be made as legless resistor. Then, the resistors are used to the SMD circuit board. Similarly, not only resistors, but also inductors, diodes, capacitors, etc. any parts with legs two ends can be made based on above steps.

The present invention has the following advantages:

1. In the present invention, legless resistors are made from leg type resistors so that cost is reduced.

2. No other machine for manufacturing legless resistors is required, the conventional machine for leg type resistors can be used. The coating machine for legless resistors is needed.

3. No hole is necessary to be drilled on a conventional printed circuit board.

4. The metal caps are appended after coating, no paint will adhere to the metal cap so that the yield ratio is high.

5. A gap is formed between the legless electronic part and the metal cap, and therefore, heat dissipation is good.

6. Other then small size legless electronic parts, legless winding resistors and large size electronic parts can be used.

Therefore, the manufacturing method for legless electronic parts of the present invention can be used to make legless electronic parts by the conventional way for manufacturing leg type electronic parts so as to be used in SMD printed circuit boards. Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A manufacturing method for legless electronic parts used in a surface mounting type printing circuit board; the legless electronic parts being made from leg type electronic elements, the method comprising the steps of:
(a) manufacturing a leg type electronic part and painting;
(b) cutting legs of a leg type resistor to become legless electronic parts;
(c) pressing metal caps into two ends of the legless parts for replacing the legs;
(d) testing the resistance of a legless parts for determining resistance, error and fault ratio of the legless parts.

2. The manufacturing method for legless electronic parts as claim in claim 1, further comprising step (e) of removing unqualified parts

3. The manufacturing method for legless electronic parts as claim in claim 1, further comprising step (e) of packing the tested parts.
